(19) United States
(12) Patent Application Publication
(10) Pub. No.: US 2025/0096521 A1
(43) Pub. Date: Mar. 20, 2025

(54) LIGHT-EMITTING DEVICE

(71) Applicant: NICHIA CORPORATION, Anan-shi (JP)

(72) Inventor: Tadayuki KITAJIMA, Itano-gun (JP)

(21) Appl. No.: 18/884,080

(22) Filed: Sep. 12, 2024

(30) Foreign Application Priority Data
Sep. 14, 2023 (JP) 2023-149184

(51) Int. Cl. H01S 5/02315; H01S 5/02255

(52) U.S. Cl. CPC H01S 5/02315; H01S 5/02255

(57) ABSTRACT

A light-emitting device includes a package and a semiconductor laser element. The package includes a frame portion, a lid portion, a base having a thickness in a range from 100 μm to 500 μm, and a first metal member arranged on upper or lower surface of the base, the first metal member having a thickness in a range from 10 μm to 150 μm. The base includes an insulating member having upper and lower surfaces respectively defining the upper and lower surfaces of the base. The insulating member defines a first through hole extending from the upper surface to the lower surface of the insulating member. A first conductive member is arranged in the first through hole. The first metal member covers the first through hole. The semiconductor laser element is electrically connected to the first conductive member and the first metal member.

### CROSS-REFERENCE TO RELATED APPLICATION

This application claims priority to Japanese Patent Application No. 2023-149184, filed on Sep. 14, 2023, the disclosure of which is hereby incorporated herein by reference in its entirety.

### TECHNICAL FIELD

The present disclosure relates to a light-emitting device.

### BACKGROUND

Japanese Patent Publication No. 2019-212752 discloses a light-emitting device in which a semiconductor laser element is disposed in a package. In this light-emitting device, the semiconductor laser element is disposed in a sealed space in consideration of the influence of dust collection.

### SUMMARY

A disclosure for achieving size reduction of a light-emitting device or simplification of components while making a space in which a semiconductor laser element is disposed in a sealed space is disclosed.

Alternatively, instead of the disclosure for solving the above-described issue, a disclosure for solving the issue of suppressing warpage of a package of a light-emitting device is disclosed.

Alternatively, instead of the disclosures for solving the above-described issues, there is a disclosure for solving the issue of improving the accuracy of the direction of light emitted from a semiconductor laser element while making a space in which the semiconductor laser element is disposed a sealed space.

Alternatively, instead of the disclosures for solving the above-described issues, a disclosure for solving the issue of accurately mounting other components on a mounting surface of a package is disclosed.

Alternatively, instead of the disclosures for solving the above-described issues, a disclosure for solving the issue of improving the heat dissipation of a package is disclosed.

In the present specification, a disclosure for solving a plurality of issues among the above-described issues in combination is also disclosed.

A light-emitting device disclosed in an embodiment includes a package and a semiconductor laser element. The package includes a frame portion, a lid portion, a base having an upper surface and a lower surface, the base having a thickness in a range from 100 μm to 500 μm, and a first metal member arranged on the upper surface or the lower surface of the base, the first metal member having a thickness in a range from 10 μm to 150 μm. The semiconductor laser element is disposed in a sealed internal space of the package. The base includes an insulating member having an upper surface and a lower surface respectively defining the upper surface and the lower surface of the base. The insulating member defines a first through hole extending from the upper surface to the lower surface of the insulating member. The base includes a first conductive member arranged in the first through hole. The first metal member is arranged on the upper surface or the lower surface of the insulating member such that the first metal member covers the first through hole. The semiconductor laser element is electrically connected to the first conductive member and the first metal member.

A light-emitting device disclosed in another embodiment includes a package and a semiconductor laser element. The package includes a frame portion, a lid portion, a base having an upper surface and a lower surface, the base having a thickness from the upper surface to the lower surface in a range from 100 μm to 500 μm, and a sealing member provided on the upper surface or the lower surface of the base, the sealing member having a thickness in a range from 10 μm to 150 μm. The semiconductor laser element is disposed in a sealed internal space of the package. The base includes an insulating member having an upper surface and a lower surface respectively defining the upper surface and the lower surface of the base. The insulating member defines a first through hole extending from the upper surface to the lower surface. The base includes a first conductive member arranged in the first through hole. The sealing member is arranged on the upper surface or the lower surface of the insulating member such that the sealing member covers the first through hole. The semiconductor laser element is electrically connected to the first conductive member.

In one embodiment or at least one of a plurality of embodiments, size reduction of a light-emitting device or simplification of components can be achieved while making a space in which a semiconductor laser element is disposed a sealed space.

### BRIEF DESCRIPTION OF DRAWINGS

FIG. 1 is a schematic perspective view of a light-emitting device according to some embodiments.

FIG. 2 is a schematic side view of the light-emitting device according to some embodiments.

FIG. 3 is a schematic cross-sectional view of a light-emitting device according to a first embodiment taken along cross-sectional line III-III in FIG. 1.

FIG. 4 is a schematic perspective view illustrating an internal state of a package of the light-emitting device according to the first embodiment.

FIG. 5 is a schematic top view of the light-emitting device in the same state as that in FIG. 4.

FIG. 6 is a schematic bottom view of the package according to some embodiments.

FIG. 7 is a schematic cross-sectional view of the package according to the first embodiment taken along cross-sectional line VII-VII in FIG. 6.

FIG. 8 is a schematic top view of a state in which a lid body is removed from the package according to the first embodiment.

FIG. 9 is a schematic cross-sectional view of a light-emitting device according to a second embodiment and a third embodiment taken along cross-sectional line IX-IX in FIG. 1.

FIG. 10 is a schematic cross-sectional view of a package according to the second embodiment and the third embodiment taken along cross-sectional line X-X in FIG. 6.

FIG. 11 is a schematic perspective view illustrating an internal state of the package of the light-emitting device according to the second embodiment.

FIG. 12 is a schematic top view of the light-emitting device in a state like that in FIG. 11.

FIG. 13 is a schematic perspective view illustrating an internal state of the package of the light-emitting device according to the third embodiment.

FIG. 14 is a schematic top view of the light-emitting device in a state like that in FIG. 12.

### DETAILED DESCRIPTIONS

In the present specification or the claims, polygons such as triangles and quadrangles, including shapes in which the corners of the polygon are rounded, beveled, chamfered, or coved, are referred to as polygons. A shape obtained by processing not only the corners (ends of a side) but also an intermediate portion of the side is similarly referred to as a polygon. That is, a shape that is partially processed while remaining a polygon shape as a base is included in the interpretation of “polygon” described in the present specification and the claims.

The same applies not only to polygons but also to words representing specific shapes such as trapezoids, circles, protrusions, and recesses. The same applies when dealing with each side forming that shape. That is, even if processing is performed on a corner or an intermediate portion of a certain side, the interpretation of “side” includes the processed portion. When a “polygon” or “side” not partially processed is to be distinguished from a processed shape, “exact” will be added to the description as in, for example, “exact quadrangle.”

Further, in the present specification or the claims, descriptions such as upper and lower (upward/downward), left and right, surface and reverse, front and back (forward/backward), and near and far are used merely to describe the relative relationship of positions, orientations, and directions, and the expressions do not necessarily match an actual relationship at the time of use.

In the drawings, directions such as an X direction, a Y direction, and a Z direction may be indicated by using arrows. The directions of the arrows are consistent across multiple drawings of the same embodiment. In addition, in the drawings, the directions of the arrows marked with X, Y, and Z are the positive directions, and the opposite directions are the negative directions. For example, the direction marked with X at the tip of the arrow is the X direction and the positive direction. In the present specification, the direction that is the X direction and is the positive direction will be referred to as the “positive direction of X” and the direction opposite to this will be referred to as the “negative direction of X.” The term “X direction” includes both the positive direction and the negative direction. The same applies to the Y direction and the Z direction.

In addition, in the present specification, when a certain object is specified as “one or more” and the object is described, an embodiment in which the object is one and an embodiment in which the object is plural are collectively described. Thus, a description specified as “one or more” supports every case of an embodiment including one or more objects, an embodiment including at least one object, and an embodiment including a plurality of objects.

In addition, in the present specification, the description illustrating “one or each” object is a description summarizing a description of one object in an embodiment including the one object, a description of one object in an embodiment including a plurality of objects, and a description of each of a plurality of objects in an embodiment including the plurality of objects. Thus, the description illustrating “one or each” object supports every case of an embodiment including one object in which the one object satisfies the described content, an embodiment including a plurality of objects in which, among these objects, at least one of the objects satisfies the described content, and an embodiment including a plurality of objects in which each of these plurality of objects satisfies the described content, and an embodiment including one or more objects in which all of the objects satisfy the described content.

The term “member” or “portion” may be used to describe, for example, a component in the present specification. The term “member” refers to an object physically treated alone. The object physically treated alone can be an object treated as one component in a manufacturing process. Meanwhile, the term “portion” refers to an object that does not have to be physically treated alone. For example, the term “portion” is used when part of one member is partially considered, or a plurality of members are collectively considered as one object.

The distinction between “member” and “portion” described above does not indicate an intention to consciously limit the scope of right in interpretation of the doctrine of equivalents. That is, even when a component described as “member” is present in the claims, this does not mean that the applicant recognizes that physically treating the component alone is essential in the application of the present disclosure.

In the present specification or the claims, when a plurality of pieces of the identical component are present and these components are to be indicated separately, the components may be distinguished by adding the terms “first” and “second” at the beginning of the names of the components. Objects to be distinguished may differ between the present specification and the claims. Thus, even when a component in the claims is given the same term as that in the present specification, the object identified by that component is not the same across the present specification and the claims in some cases.

For example, when components distinguished by being termed “first”, “second”, and “third” are present in the present specification, and when components given the terms “first” and “third” in the present specification are described in the claims, these components may be distinguished by being denoted as “first” and “second” in the claims for ease of understanding. In this case, the components denoted as “first” and “second” in the claims refer to the components termed “first” and “third” in the present specification, respectively. This rule applies to not only components but also other objects in a reasonable and flexible manner.

Embodiments for implementing the present disclosure will be described below. Specific embodiments for implementing the present disclosure will be described below with reference to the drawings. Embodiments for implementing the present disclosure are not limited to the specific embodiments. That is, the embodiments illustrated by the drawings are not the only form in which the present disclosure is realized. Sizes and positional relationships of members illustrated in each of the drawings may sometimes be exaggerated in order to facilitate understanding.

### First Embodiment

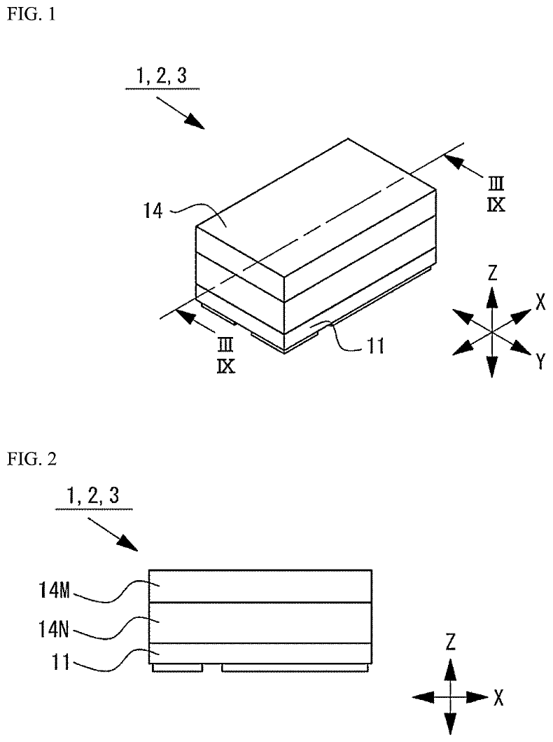

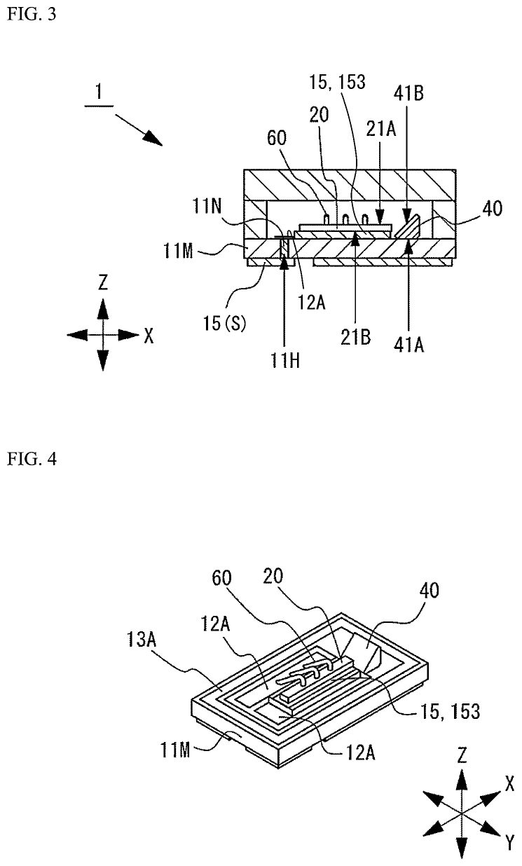

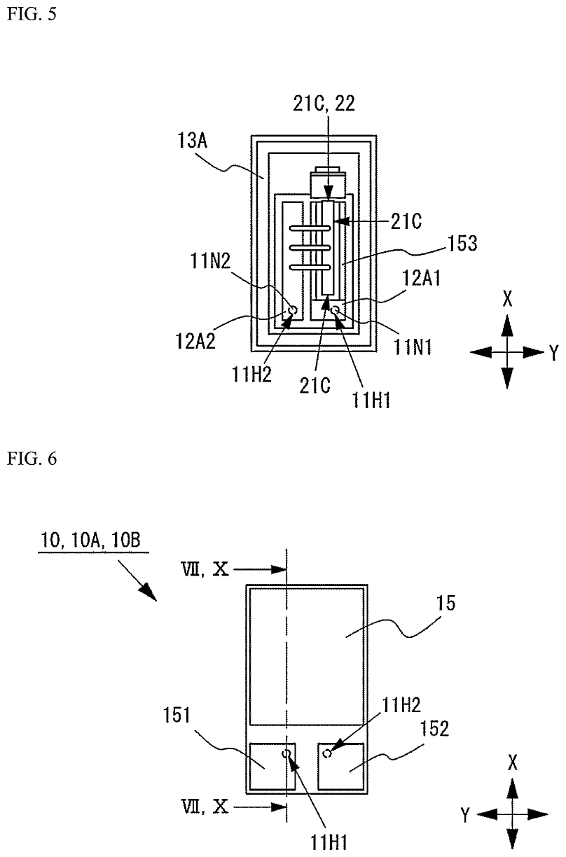

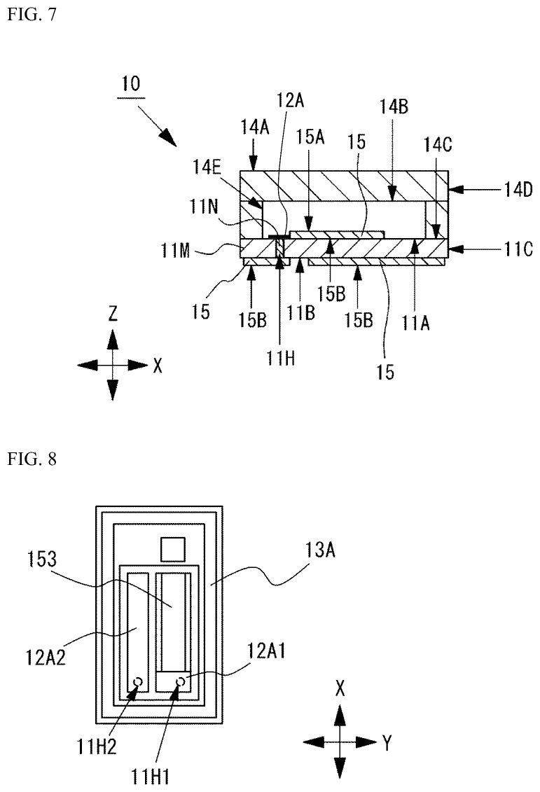

A light-emitting device 1 according to a first embodiment will now be described. FIGS. 1 to 8 are views for explaining an exemplary form of the light-emitting device 1. FIG. 1 is a schematic perspective view of the light-emitting device 1. FIG. 2 is a schematic side view of the light-emitting device 1. FIG. 3 is a schematic cross-sectional view of the light-emitting device 1 taken along cross-sectional line III-III in FIG. 1. FIG. 4 is a schematic perspective view illustrating an internal state of a package 10 of the light-emitting device 1. FIG. 5 is a schematic top view of the light-emitting device 1 in the same state as that in FIG. 4. FIG. 6 is a schematic bottom view of the package 10. FIG. 7 is a schematic cross-sectional view of the package 10 taken along cross-sectional line VII-VII in FIG. 6. FIG. 8 is a schematic top view of the package 10 illustrated in a state in which a lid body 14 is removed from the package 10. In FIGS. 5, 6, and 8, a first through hole 11H1 and a second through hole 11H2 are indicated by broken lines.

The light-emitting device 1 includes a plurality of components. The plurality of components include the package 10, one or more semiconductor laser elements 20, one or more reflective members 40, and one or more wirings 60.

The light-emitting device 1 may include a component other than the components described above. For example, the light-emitting device 1 may further include a semiconductor laser element in addition to the one or more semiconductor laser elements 20. The light-emitting device 1 does not have to include some of the components described above.

Firstly, each of the components will be described.

### Package 10

The package 10 includes a base 11 and the lid body 14. The package 10 includes one or more sealing members S (see FIG. 3). In this embodiment, the sealing members S are the metal members 15. The lid body 14 is bonded to the base 11 to form the package 10. An internal space in which other components are disposed is defined in the package 10. The internal space is a closed space surrounded by the base 11 and the lid body 14. The internal space can also be a sealed space in a vacuum or airtight state.

The outer edge shape of the package 10 in a top view is rectangular. This rectangular shape can be a rectangular shape with long sides and short sides. In the illustrated package 10, the long-side direction of the rectangular shape is the same direction as the X direction, and the short-side direction of the rectangular shape is the same direction as the Y direction. The outer edge shape of the package 10 in a top view does not have to be rectangular.

The internal space in which other components are disposed is formed in the package 10. An upper surface 11A of the package 10 is a part of a region defining the internal space. In addition, each of inner lateral surfaces 14E and a first lower surface 14B of the package 10 are a part of a region defining the internal space.

The base 11 has the upper surface 11A and the lower surface 11B. The base 11 has one or more lateral surfaces 11C. The base 11 is formed of a flat plate with a rectangular parallelepiped shape. The base 11 does not have to have a rectangular parallelepiped shape.

An outer edge shape of the upper surface 11A is rectangular. This rectangular shape can be a rectangular shape with long sides and short sides. In the base 11 illustrated by the drawings, a long-side direction of the rectangle is the same direction as the X direction, and a short-side direction thereof is the same direction as the Y direction.

The base 11 includes an insulating member 11M having the upper surface 11A and the lower surface 11B, and one or more conductive members 11N. The insulating member 11M is provided with one or more through holes 11H. The one or each through hole 11H extends from the upper surface 11A to the lower surface 11B.

The one or each conductive member 11N is provided in the through hole 11H of the insulating member 11M. By providing the conductive member 11N in the through hole 11H, a conduction path connecting the internal space and an external space of the package 10 is formed.

The uppermost point of the conductive member 11N provided in the through hole 11H is located at the same position as the upper surface 11A of the insulating member 11M, or above the upper surface 11A. The lowest point of the conductive member 11N provided in the through hole 11H is located at the same position as the lower surface 11B of the insulating member 11M, or below the lower surface 11B.

The one or more through holes 11H include the first through hole 11H1 and the second through hole 11H2. The one or more conductive members 11N include a first conductive member 11N1 provided in the first through hole 11H1 and a second conductive member 11N2 provided in the second through hole 11H2.

The one or each metal member 15 includes an upper surface 15A and a lower surface 15B. The one or each metal member 15 is provided on the upper surface 11A or the lower surface 11B of the base 11. The one or more metal members 15 include a metal member 15 provided on the base 11 so as to cover the through hole 11H. In a top view or a bottom view, the through hole 11H is closed by the metal member 15. Thus, the airtightness of the package 10 can be improved.

A thickness of the base 11 is in a range from 100 μm to 500 μm. The thickness can be 150 μm or more. The thickness can be 300 μm or less. The thickness of the base 11 is a width of the base 11 from the upper surface 11A to the lower surface 11B.

A thickness of one or each metal member 15 is in a range from 10 μm to 150 μm. The thickness thereof can be 50 μm or more. The thickness thereof can be 100 μm or less.

The thickness of the metal member 15 is a width of the metal member 15 from the upper surface 15A to the lower surface 15B. Setting the thickness of the metal member 15 closing the through hole 11H to 10 μm or more can suppress degradation of the airtightness of the internal space of the package 10 via the through hole 11H, so that a sealed space can be achieved. Reduction of the thickness of the metal member 15 can reduce the size of the light-emitting device.

The one or each metal member 15 can be constituted by one or more metal layers. For example, the one or each metal member 15 can be constituted by a metal layer formed of a thin film having a thickness of 0.5 μm or less and a metal layer having a thickness of 10 μm or more. The metal layer formed of the thin film is used, for example, to improve the adhesion of the metal member 15 provided on the insulating member 11M.

Whether the internal space of the package 10 is a sealed space can be determined by measurement based on an immersion method (bombing method) in a standard of a standard number “JIS Z2331: 2006” and a standard name “Method for helium leak testing”. For a package in which an internal volume (mm³) of the internal space is less than 50.0 mm³, the condition of the sealed space can be that an actually measured leak amount (Pa·m³/sec) of helium gas is less than 1.0×10⁻⁷ Pa·m³/sec when the bombing pressure (Pa) of helium gas is 0.5 MPa, the pressurization time (h) of bombing is 1 h, and a dwell time (h) is within 0.1 h. Alternatively, for a package in which the internal volume (mm³) of the internal space is in a range from 0.5 mm³ to 4.0 mm³, as a condition for a high airtightness from the viewpoint of reliability and assurance, the condition of the sealed space can be that the actually measured leak amount (Pa·m³/sec) of helium gas is less than 1.0×10⁻⁹ Pa·m³/sec when the bombing pressure (Pa) of helium gas is 0.5 MPa, the pressurization time (h) of bombing is 1 h, and a dwell time (h) is within 5 h. When a product is in the state of a light-emitting device including a package and other components, a test may be performed in the state of the light-emitting device without disassembly to obtain the package. However, when an appropriate test is not able to be performed on the package due to an influence of a component other than the package, the package can be brought into a state in which an appropriate test can be performed, for example, in a state in which an affecting component is separated from the package, and then tested. For this measurement, an inspection device “MUH-0100” manufactured by FUKUDA CO., LTD. can be used, for example.

In the determination regarding whether the internal space of the package 10 is a sealed space, a test Qc: test method 2 of a sealing test by gas leakage “immersion in a liquid at a high temperature” test in a standard of a standard number “JIS C0026: 2001 (IEC 60068-22-17:1994)” and a standard name “Basic environmental testing procedures-electric/electronic-sealing (airtightness) test method” is preferably performed. In the case of a package in which a semiconductor laser element is disposed in an internal space, the temperature of a liquid in this test is assumed to be maintained at a temperature higher than a maximum operating temperature by 1° C. to 5° C. when an operating temperature range is defined as a product standard for a light-emitting device including this package. On the other hand, when no operating temperature range defined as a product standard is present, the temperature is maintained at 75° C. to 80° C. In addition, the test is performed in a state in which the uppermost portion of the package or the light-emitting device is immersed to a depth of 10 mm or more from a liquid surface. The immersion time of the package or the light-emitting device is set to 10 minutes (it is sufficient that 10 minutes or longer elapse), but when the time defined in the product standard is defined to be shorter than 10 minutes, it is sufficient that the time defined in the product standard elapse. The criteria for the test can be whether a distinct bubble stream, two or more large bubbles or attached bubble growth is observed visually by a person with a visual acuity of 1.0 or more during the test. When a product is in the state of a light-emitting device including a package and other components, the test may be performed in the state of the light-emitting device without disassembly to obtain the package. However, when an appropriate test for the package is not able to be performed, for example, due to observation of bubbles caused by a component other than the package, the package can be brought into a state in which an appropriate test can be performed, for example, in a state in which the component is separated from the package, and then tested. The test based on the test method 2 is suitable for determining the presence or absence of a larger leak compared to the measurement based on the immersion method (bombing method). Performing this test and satisfying the criteria can be a prerequisite for a sealed space. For this determination, for example, an inspection device “G-203A” manufactured by HiSOL Inc. can be used.

The one or more metal members 15 include a first metal member 151 and a second metal member 152. The first metal member 151 is provided on the insulating member 11M so as to cover the first through hole 11H1. The second metal member 152 is provided on the insulating member 11M so as to cover the second through hole 11H2.

The first metal member 151 and the second metal member 152 are provided on the same surface of the insulating member 11M. For example, the first metal member 151 and the second metal member 152 are provided on the lower surface 11B of the base 11. In this case, the lower surface 15B of the first metal member 151 and the lower surface 15B of the second metal member 152 are located lower than the lower surface 11B of the base 11. The lower surface 15B of the first metal member 151 or the lower surface 15B of the second metal member 152 can be the lowermost surface of the package 10.

The one or more metal members 15 include the first metal member 151 and a third metal member 153. The third metal member 153 is provided on a surface opposite to the surface on which the first metal member 151 is provided. For example, the first metal member 151 is provided on the lower surface 11B of the insulating member 11M, and the third metal member 153 is provided on the upper surface 11A of the insulating member 11M. Providing the metal members 15 having the same thickness on the upper and lower surfaces can suppress warpage of the package 10.

The third metal member 153 is provided on the insulating member 11M without covering the first through hole 11H1. In other words, the third metal member 153 and the first through hole 11H1 do not overlap each other in a top view. Providing the third metal member 153 without covering the first through hole 11H1 can provide the upper surface 15A of the third metal member 153 to be parallel to the upper surface 11A of the insulating member 11M with high accuracy.

A part of the third metal member 153 overlaps a part of the first metal member 151 in a top view. By making the first metal member 151 and the third metal member 153 overlap each other, the warpage of the package 10 can be suppressed.

The thickness of the insulating member 11M is greater than the thickness of the first metal member 151. The thickness of the insulating member 11M is equal to or more than the sum of the thickness of the first metal member 151 and the thickness of the third metal member 153.

Each of the through holes 11H provided in the insulating member 11M is covered with any one of all the metal members 15 provided on the upper surface 11A or the lower surface 11B. In other words, there is no through hole 11H in which neither the upper surface 11A nor the lower surface 11B is covered by the metal member 15.

With respect to the one or each through hole 11H, the distance from the through hole 11H to an outer edge of the metal member 15 covering the through hole 11H is 50 μm or more. Alternatively, this distance may be 100 μm or more. Providing the metal member 15 with a certain range from the through hole 11H likely enables the airtightness ensured.

The base 11 includes one or more wiring portions 12A. The one or more wiring portions 12A are disposed in the internal space of the package 10. The one or each wiring portion 12A is provided on the upper surface 11A of the package 10.

The one or each wiring portion 12A is connected to the conductive member 11N. The one or more wiring portions 12A include a wiring portion 12A provided covering the first through hole 11H1 or the second through hole 11H2. The one or more wiring portions 12A include a first wiring portion 12A1 provided covering the first through hole 11H1. The one or more wiring portions 12A include a second wiring portion 12A2 provided covering the second through hole 11H2.

The third metal member 153 is electrically connected to the first wiring portion 12A1. The third metal member 153 and the first wiring portion 12A1 have portions that are in physical contact with each other. For example, the lower end of a lateral surface of the third metal member 153 and the outer edge of an upper surface of the first wiring portion 12A1 come into physical contact with each other, so that the third metal member 153 and the first wiring portion 12A1 are electrically connected to each other. The first through hole 11H1 does not overlap the third metal member 153 in a top view and is covered with the first wiring portion 12A1. The package 10 includes no metal member 15 in contact with the second wiring portion 12A2.

The metal member 15 provided without covering the through hole 11H can be provided on the lower surface 11B of the base 11. This metal member 15 is larger than any one of both the first metal member 151 and the second metal member 152 in a bottom view. This metal member 15 overlaps the third metal member 153 in a top view. Thus, a heat dissipation path is formed from the third metal member 153 to this metal member 15.

In a bottom view, the first metal member 151 and the second metal member 152 are arranged side by side in the short-side direction of the bottom surface 11B. The metal member 15 that does not cover the through hole 11H is disposed spaced apart from both the first metal member 151 and the second metal member 152 in the long-side direction of the lower surface 11B. Thus, the balance of the package 10 is stabilized.

A thickness (width in the vertical direction) of the wiring portion 12A is in a range from 0.2 μm to 5 μm. The wiring portion 12A is sufficiently thinner than the metal member 15. For example, the thickness of the wiring portion 12A can be 10% or less of the thickness of the metal member 15.

All the through holes 11H extending from the upper surface 11A to the lower surface 11B of the base 11 are covered by the metal member 15 on at least one of the upper surface 11A side and the lower surface 11B side. Because there is no through hole 11H not covered by the metal member 15, the airtightness of the package 10 can be improved.

Between the “plurality of metal members 15” as all the metal members 15 provided on the upper surface 11A or the lower surface 11B of the base 11 and the “plurality of through holes 11H” as all the through holes 11H extending from the upper surface 11A to the lower surface 11B of the base 11, there is a relationship that each of the “plurality of through holes 11H” is covered by any of the “plurality of metal members 15”. The “plurality of metal members 15” include at least the first metal member 151 and the second metal member 152, and “the plurality of through holes 11H” include at least the first through hole 11H1 and the second through hole 11H2.

The base 11 includes a bonding pattern 13A. The bonding pattern 13A is provided on the upper surface 11A. The bonding pattern 13A is provided annularly. The bonding pattern 13A is provided in a rectangular annular shape. In a top view, the bonding pattern 13A is provided in the vicinity of the outer edge of the upper surface 11A.

The bonding pattern 13A does not cover the through hole 11H. That is, in a top view, the bonding pattern 13A does not overlap any through hole 11H. A thickness of the bonding pattern 13A is in a range from 0.2 μm to 5 μm. The less the thickness of the bonding pattern 13A is, the narrower the width of the package in the vertical direction can be. The thickness of the bonding pattern 13A is smaller than the thickness of the metal member 15. The thickness of the bonding pattern 13A may be equal to or more than the thickness of the metal member 15.

The base 11 can be formed using a ceramic as a main material, for example. Examples of the ceramic as the main material of the base 11 include aluminum nitride, silicon nitride, aluminum oxide, and silicon carbide.

The main material as used herein refers to a material that accounts for the greatest proportion of a target formed product in terms of mass or volume. When a target formed product is formed of a single material, the material is the main material. That is, when a certain material is the main material, the proportion of the material can be 100%.

The conductive member 11N can be formed using a metal material as a main material, for example. Examples of the metal material as the main material of the conductive member 11N include single-component metals, such as Cu, Ag, Ni, Cr, and W, and alloys containing any of these metals. The conductive member 11N can be constituted by one or more metal layers, for example.

The metal member 15 can be formed using a metal material as a main material. Examples of the metal material as the main material of the metal member 15 include single-component metals, such as Cu, Ag, Ni, Au, Ti, Pt, Pd, Cr, and W, and alloys containing any of these metals. The metal member 15 can be constituted by one or more metal layers, for example. The metal member 15 can be formed on the upper surface 11A or the lower surface 11B of the base 11 by a process such as plating or bonding, for example.

The wiring portion 12A can be formed using a metal material as a main material, for example. Examples of the metal material as the main material of the wiring portion 12A include single-component metals, such as Cu, Ag, Ni, Au, Ti, Pt, Pd, Cr, and W, and alloys containing any of these metals. The wiring portion 12A can be constituted by one or more metal layers, for example. The wiring portion 12A can be formed on the upper surface 11A or the lower surface 11B of the base 11 by a process such as plating, sputtering, or vapor deposition.

The bonding pattern 13A can be formed using a metal material as a main material, for example. Examples of the metal material as the main material of the bonding pattern 13A include single-component metals, such as Cu, Ag, Ni, Au, Sn, Ti, and Pd, and alloys containing any of these metals. The bonding pattern 13A can be constituted by one or more metal layers, for example.

The lid body 14 has an upper surface 14A and a first lower surface 14B. The lid body 14 has a second lower surface 14C. The lid body 14 also has one or more outer lateral surfaces 14D. The lid body 14 also has one or more inner lateral surfaces 14E. The one or more outer lateral surfaces 14D meet the upper surface 14A. The one or more outer lateral surfaces 14D meet the second lower surface 14C. The one or more inner lateral surfaces 14E meet the first lower surface 14B. The one or more inner lateral surfaces 14E meet the second lower surface 14C.

In a top view, an outer edge shape of the lid body 14 is rectangular. In a top view, the outer edge shape of the lid body 14 is the outer edge shape of the package 10. In a top view, the outer edge shape of the upper surface 14A is rectangular. This rectangular shape can be a rectangular shape with long sides and short sides. The long-side direction of the upper surface 14A is parallel to the long-side direction of the outer edge shape of the lid body 14. In a top view, the outer edge shape of the upper surface 14A does not have to be rectangular.

In a bottom view, the first lower surface 14B is surrounded by the second lower surface 14C. The second lower surface 14C is an annular surface surrounding the first lower surface 14B in a bottom view. The second lower surface 14C is a rectangular annular surface. A frame defined by an inner edge of the second lower surface 14C is referred to as an inner frame of the second lower surface 14C, and a frame defined by an outer edge of the second lower surface 14C is referred to as an outer frame of the second lower surface 14C.

The lid body 14 includes a recessed portion surrounded by the frame formed by the second lower surface 14C. The recessed portion defines a portion of the lid body 14 recessed upward from the second lower surface 14C. The first lower surface 14B is a part of the recessed portion. The one or more inner lateral surfaces 14E are a part of the recessed portion. The first lower surface 14B is located above the second lower surface 14C.

The lid body 14 includes a lid portion 14M and a frame portion 14N. The lid portion 14M and the frame portion 14N may be members formed of mutually different materials. The lid body 14 can include a lid member corresponding to the lid portion 14M and a frame member corresponding to the frame portion 14N.

The lid portion 14M includes the upper surface 14A. The lid portion 14M includes the first lower surface 14B. The frame portion 14N includes the second lower surface 14C. The frame portion 14N includes the one or more outer lateral surfaces 14D and the one or more inner lateral surfaces 14E.

The lid body 14 is bonded to the base 11. The second lower surface 14C of the lid body 14 is bonded to the upper surface 11A of the base 11. The lid body 14 is bonded to the bonding pattern 13A of the base 11. The lid body 14 is bonded to the base 11 via an adhesive.

The lid body 14 has light transmissivity to transmit light. The description “light transmissivity” as used herein refers to that the transmittance for light incident on the lid body 14 is equal to or more than 80%. The lid body 14 may partially include a non-light transmitting region (a region with no light transmissivity).

The lid body 14 can be formed using glass as a main material, for example. The lid body 14 may be formed using a lid member and a frame member formed using mutually different main materials. The lid member can be formed using, for example, a light transmitting material such as glass or sapphire as a main material. The frame member may be formed using, for example, glass or ceramic as a main material. Examples of the ceramic as the main material of the frame member include aluminum nitride, silicon nitride, aluminum oxide, and silicon carbide.

A length of the package 10 in the X direction can be in a range from 1 mm to 3 mm. A length of the package 10 in the Y direction can be in a range from 2 mm to 4 mm. A length of the package 10 in the Z direction can be in a range from 1 mm to 3 mm. Thus, the light-emitting device 1 can be reduced in size. The length of the internal space of the package 10 in the X direction can be in a range from 0.7 mm to 2.4 mm. The length of the internal space of the package 10 in the Y direction can be in a range from 1.7 mm to 3.6 mm. The length of the internal space of the package 10 in the Z direction can be in a range from 0.3 mm to 1.5 mm. The internal volume of the internal space of the package 10 can be in a range from 0.357 mm³ to 12.96 mm³.

### Semiconductor Laser Element 20

The semiconductor laser element 20 has an upper surface 21A, a lower surface 21B, and a plurality of lateral surfaces 21C. A shape of the upper surface 21A is a rectangle having long sides and short sides. In a top view, an outer shape of the semiconductor laser element 20 is a rectangle having long sides and short sides. The shape of the upper surface 21A and the outer shape of the semiconductor laser element 20 in a top view are not limited thereto.

The semiconductor laser element 20 has a light-emitting surface 22 from which light is emitted. For example, the lateral surface 21C can serve as the light-emitting surface 22. The lateral surface 21C serving as the light-emitting surface 22 meets the short side of the upper surface 21A. For example, the upper surface 21A can serve as the light-emitting surface 22.

As the semiconductor laser element 20, a single-emitter semiconductor laser element including one emitter can be employed. As the semiconductor laser element 20, a multi-emitter semiconductor laser element including a plurality of emitters can be employed.

As the semiconductor laser element 20, for example, a semiconductor laser element that emits blue light can be employed. Also, as the semiconductor laser element 20, for example, a semiconductor laser element that emits green light can be employed. Also, for example, as the semiconductor laser element 20, a semiconductor laser element that emits red light can be employed. As the semiconductor laser element 20, a semiconductor laser element that emits light of another color or light having another wavelength may be employed.

Here, blue light refers to light having a light emission peak wavelength within a range from 420 nm to 494 nm. Green light refers to light having a light emission peak wavelength within a range from 495 nm to 570 nm. Red light refers to light having a light emission peak wavelength within a range from 605 nm to 750 nm.

Examples of the semiconductor laser element 20 that emits blue light or the semiconductor laser element 20 that emits green light include a semiconductor laser element including a nitride semiconductor. A GaN-based semiconductor, such as GaN, InGaN, or AlGaN, can be employed as the nitride semiconductor. Examples of the semiconductor laser element 20 that emits red light include a semiconductor laser element including an InAlGaP-based semiconductor, a GaInP-based semiconductor, or a GaAs-based semiconductor such as GaAs or AlGaAs.

The semiconductor laser element 20 emits a directional laser beam. Divergent light that spreads is emitted from the light-emitting surface 22 (emission end surface) of the semiconductor laser element 20. The light emitted from the semiconductor laser element 20 forms a far-field pattern (hereinafter, referred to as an “FFP”) with an elliptical shape in a plane parallel to the light-emitting surface 22. The FFP indicates a shape or a light intensity distribution of the emitted light at a position spaced apart from the light-emitting surface of the semiconductor laser element.

Here, light passing through the center of the elliptical shape of the FFP, in other words, light having a peak intensity in the light intensity distribution of the FFP is referred to as light traveling along an optical axis or light passing through an optical axis. Based on the light intensity distribution of the FFP, light having an intensity that is equal to or more than 1/e² with respect to the peak intensity is referred to as a main portion of the light.

The FFP of the light emitted from the semiconductor laser element 20 has an elliptical shape in which the length in a layering direction is greater than that in a direction perpendicular to the layering direction in the plane parallel to the light-emitting surface 22. The layering direction is a direction in which a plurality of semiconductor layers including an active layer are layered in the semiconductor laser element 20. The direction perpendicular to the layering direction can also be referred to as a plane direction of the semiconductor layer. A long diameter direction of the elliptical shape of the FFP can also be referred to as a fast axis direction of the semiconductor laser element 20, and a short diameter direction of the elliptical shape of the FFP can also be referred to as a slow axis direction of the semiconductor laser element 20.

Based on the light intensity distribution of the FFP, an angle at which light having a light intensity of 1/e² of a peak light intensity spreads is referred to as a divergence angle of light of the semiconductor laser element 20. Here, the divergence angle of light is indicated as an angle formed by light having the peak light intensity (light passing through an optical axis) and light having a light intensity of 1/e² of the peak light intensity. In some cases, the divergence angle of light can also be determined based on, for example, the light intensity that is half of the peak light intensity, other than being determined based on the light intensity of 1/e² of the peak light intensity. In the description herein, the term “divergence angle of light” by itself refers to a divergence angle of light at a light intensity of 1/e² of the peak light intensity.

The divergence angle in the fast axis direction of the light emitted from the semiconductor laser element 20 can be in a range from 15° to less than 90°. The divergence angle of the light in the slow axis direction can be more than 0° and 8° or less. Also, the divergence angle of the light in the fast axis direction is greater than the divergence angle of the light in the slow axis direction.

### Reflective Member 40

The reflective member 40 has a lower surface 41A, and a light-reflective surface 41B that reflects light. The light-reflective surface 41B is inclined with respect to the lower surface 41A. A straight line connecting a lower end and an upper end of the light-reflective surface 41B is inclined with respect to the lower surface 41A. An angle at which the light-reflective surface 41B is inclined with respect to the lower surface 41A is referred to as an inclination angle of the light-reflective surface 41B.

The light-reflective surface 41B is a flat surface. The light-reflective surface 41B may be a curved surface. The inclination angle of the light-reflective surface 41B is 45°. The inclination angle of the light-reflective surface 41B does not have to be 45°.

As the main material of the reflective member 40, glass or metal can be used. A heat-resistant material is preferably used as the main material of the reflective member 40. As the main material, for example, a glass such as quartz glass or borosilicate glass (BK7), or a metal such as Al can be used. The reflective member 40 can also be formed using Si as the main material.

When the main material is a reflective material such as Al, the light-reflective surface 41B can be formed of the main material. Instead of forming the light-reflective surface 41B with the main material, a main body of the reflective member 40 may be formed with the main material, and the light-reflective surface 41B may be formed on a surface of the main body. In this case, the light-reflective surface 41B can be formed using, for example, a layer of a metal such as Ag or Al, or a dielectric multilayer film of Ta₂O₅/SiO₂, TiO₂/SiO₂, Nb₂O₅/SiO₂, or the like.

In the light-reflective surface 41B, the reflectance with respect to the peak wavelength of the light with which the light-reflective surface 41B is irradiated is equal to or more than 90%. The reflectance may be equal to or more than 95%. The reflectance may be equal to or more than 99%. The light reflectance is equal to or less than 100% or is less than 100%.

### Wiring 60

The wiring 60 is a linear conductive material having bonding portions at both ends. The bonding portions at both ends serve as portions for bonding with other components. The wiring 60 is used for electrical connection between two components. The wiring 60 is, for example, a metal wire. The metal used can be, for example, gold, aluminum, silver, or copper.

Subsequently, the light-emitting device 1 will be described.

### Light-Emitting Device 1

In the light-emitting device 1, one or each semiconductor laser element 20 is disposed in the internal space of the package 10. Thus, a space in which the semiconductor laser element 20 is disposed can be a sealed space.

The one or each semiconductor laser element 20 is disposed on the upper surface 11A of the base 11. The one or each semiconductor laser element 20 is disposed on the upper surface 11A of the base 11 via the metal member 15.

The one or each semiconductor laser element 20 is disposed on the upper surface 15A of the metal member 15. Disposition of the semiconductor laser element 20 on the metal member 15 can raise the position of a light-emitting point of the semiconductor laser element 20.

The one or each semiconductor laser element 20 is directly bonded to the metal member 15. The term “directly” means that no component other than an adhesive is present between the semiconductor laser element 20 and the metal member 15. Thus, the components of the light-emitting device 1 can be simplified.

The metal member 15 on which the semiconductor laser element 20 is disposed is electrically connected to the conductive member 11N of the package 10. The semiconductor laser element 20 is electrically connected to the conductive member 11N and the metal member 15 provided covering the through hole 11H in which the conductive member 11N is provided. For example, the semiconductor laser element 20 is electrically connected to the first conductive member 11N1 and the first metal member 151. The semiconductor laser element 20 is also electrically connected to the second conductive member 11N2 and the second metal member 152.

The semiconductor laser element 20 is disposed on the upper surface 15A of the third metal member 153. Because the upper surface 15A of the third metal member 153 is accurately parallel to the upper surface 11A of the base 11, the accuracy of the direction of light emitted from the semiconductor laser element 20 is also improved.

By providing the third metal member 153 on the upper surface 11A of the base 11 so as not to cover the through hole 11H and providing the first metal member 151 on the lower surface 11B of the base 11 so as to cover the through hole 11H, advantages can be achieved in both the airtightness of the internal space of the package 10 and the accuracy of the direction of light emitted from the semiconductor laser element 20.

In addition to the first metal member 151, by providing the second metal member 152 covering the second through hole 11H2 on the lower surface 11B of the base 11, the lowermost surface of the package 10 immediately below the first through hole 11H1 and the lowermost surface of the package 10 immediately below the second through hole 11H2 can be aligned with each other, which leads to stabilization of the package 10.

The semiconductor laser element 20 is disposed such that the long-side direction of the upper surface 21A is parallel to the long-side direction of the package 10. This arrangement leads to size reduction of the light-emitting device 1.

The one or each semiconductor laser element 20 emits light laterally from the lateral surface 21C serving as the light-emitting surface 22. The one or each semiconductor laser element 20 emits light that travels in the first direction. In the illustrated light-emitting device 1, the first direction is the same direction as the X direction. The optical axis of light emitted from the one or each semiconductor laser element 20 is the same direction as the X direction.

The distance from the upper surface 11A of the package 10 to the lower surface 21B of the semiconductor laser element 20 in the direction perpendicular to the upper surface 11A of the package 10 is more than 0 μm and 150 μm or less. This distance is preferably in a range from 50 μm to 130 μm. Thus, the light-emitting device 1 can be reduced in size.

In the light-emitting device 1, the one or more reflective members 40 are disposed in the internal space of the package 10. One or each reflective member 40 reflects light emitted from the semiconductor laser element 20. The reflective member 40 is disposed at a position away from the semiconductor laser element 20 in the first direction.

Light traveling in the first direction from the semiconductor laser element 20 is reflected by the reflective member 40. The light-reflective surface 41B of the reflective member 40 reflects light emitted laterally from the semiconductor laser element 20 upward.

In a top view, the one or each reflective member 40 is disposed at a position not overlapping the through hole 11H. The lower surface 41A of the reflective member 40 can be prevented from being mounted obliquely with respect to the lower surface 11B of the base 11 due to the conductive member 11N, allowing the lower surface 41A of the reflective member 40 to be mounted with high accuracy.

In a top view, the second through hole 11H2 is provided at a position away from the semiconductor laser element 20 in the second direction and a position away from the reflective member 40 in the second direction. Thus, the ratio of the length in the long-side direction to the length in the short-side direction of the package 10 can be reduced in a top view. When the length in the long-side direction is increased, a stress in the long-side direction is increased, which affects the mounting accuracy of the semiconductor laser element 20.

In the light-emitting device 1, the one or more wirings 60 are provided to electrically connect the one or more semiconductor laser elements 20 to the package 10. The one or more wirings 60 include a wiring 60 having one end bonded to the upper surface 21A of the semiconductor laser element 20 and the other end bonded to the wiring portion 12A. The one or more wirings 60 include a wiring 60 having one end bonded to the upper surface 21A of the semiconductor laser element 20 and the other end bonded to the second wiring portion 12A2. A plurality of wirings 60 are bonded to the upper surface 21A of one semiconductor laser element 20.

When the number of semiconductor laser elements 20 included in the light-emitting device 1 is one, the internal volume of the internal space of the package 10 is preferably in a range from 0.357 mm³ to 2 mm³. Thus, the light-emitting device 1 can be reduced in size.

When the number of semiconductor laser elements 20 included in the light-emitting device 1 is two, the internal volume of the internal space of the package 10 is preferably in a range from 0.6 mm³ to 4 mm³. Thus, the light-emitting device 1 can be reduced in size.

Although the light-emitting device 1 according to the first embodiment has been described above, in the light-emitting device 1, a sealing member S (see FIG. 3) serving to close the through hole 11H does not have to be limited to a member (the metal member 15) whose main material is metal. By employing the first metal member 151 and the second metal member 152, the metal member 15 can also be electrically connected to the semiconductor laser element 20; however, in terms of sealing of the package 10, a non-conductive sealing member that has a similar configuration as the metal member 15 described above can be employed as long as the sealing member has a predetermined thickness or more and can block leakage of gas.

### Second Embodiment

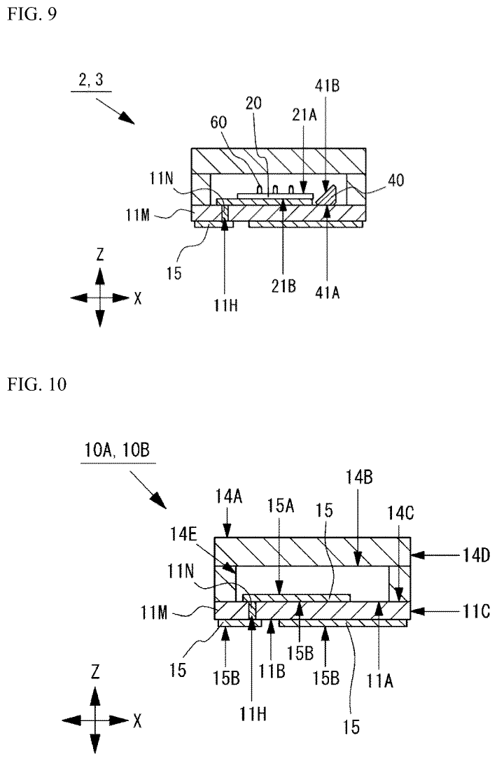

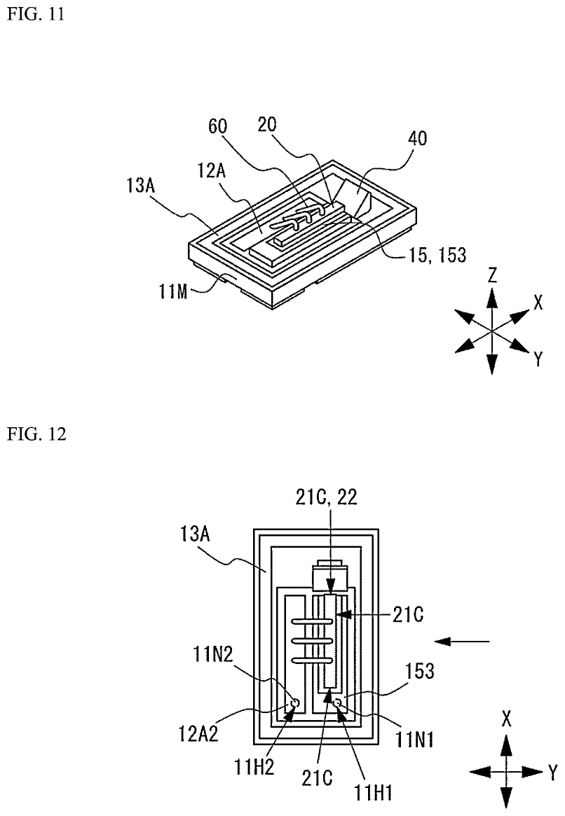

A light-emitting device 2 according to the second embodiment will now be described. FIG. 1, FIG. 2, FIG. 6, and FIGS. 9 to 12 are views for explaining an exemplary form of the light-emitting device 2. FIG. 1 is a schematic perspective view of the light-emitting device 2. FIG. 2 is a schematic side view of the light-emitting device 2. FIG. 6 is a schematic bottom view of a package 10A. FIG. 9 is a schematic cross-sectional view of the light-emitting device 2 taken along cross-sectional line IX-IX in FIG. 1. FIG. 10 is a schematic cross-sectional view of the package 10A taken along cross-sectional line X-X in FIG. 6. FIG. 11 is a schematic perspective view illustrating an internal state of the package 10A of the light-emitting device 2. FIG. 12 is a schematic top view of the light-emitting device 2 in a state like that in FIG. 11.

All descriptions related to the light-emitting device 1 and the components of the first embodiment described above apply to the description of the light-emitting device 2 except for the contents that can be said to be inconsistent from the views of FIG. 1, FIG. 2, FIG. 6, and FIGS. 9 to 12 according to the light-emitting device 2. All non-contradictory contents will not be repeated here in order to avoid duplication.

The light-emitting device 2 includes a plurality of components. The plurality of components include the package 10A, the one or more semiconductor laser elements 20, the one or more reflective members 40, and the one or more wirings 60.

### Package 10A

In the package 10A, the third metal member 153 is provided on the insulating member 11M so as to cover the first through hole 11H1. In other words, the third metal member 153 and the first through hole 11H1 overlap each other in a top view. By providing the metal members 15 on the upper and lower surfaces of the insulating member 11M, the airtightness of the internal space can be improved.

Because the first through hole 11H1 is covered by the third metal member 153 in the package 10A, the first wiring portion 12A1 provided covering the first through hole 11H1 in the package 10 is not necessary in the package 10A.

### Light-Emitting Device 2

In the light-emitting device 2, the semiconductor laser element 20 is disposed on the upper surface 11A of the third metal member 153, and the third metal member 153 closes the first through hole 11H1. In a top view, the semiconductor laser element 20 and the first through hole 11H1 do not overlap each other. Thus, because the third metal member 153 can be extended in the longitudinal direction of the semiconductor laser element 20, heat dissipation can be improved.

### Third Embodiment

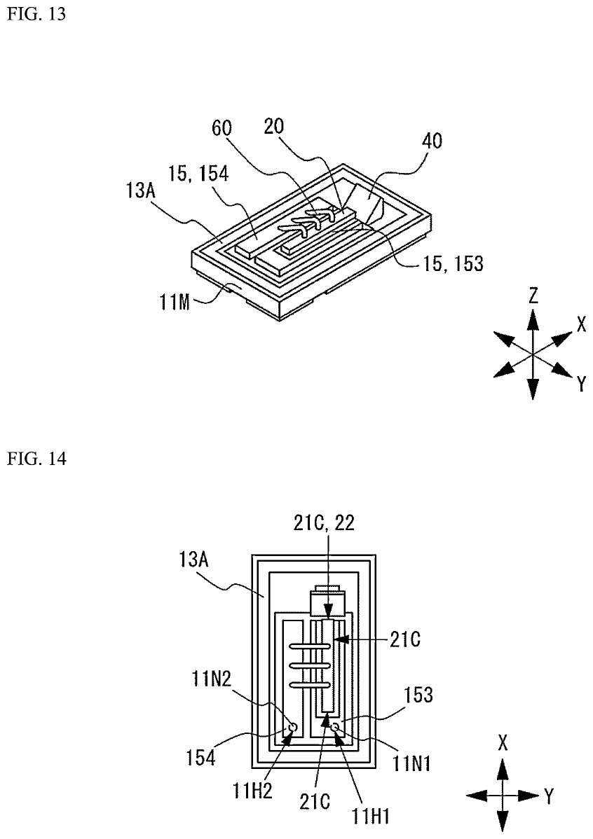

A light-emitting device 3 according to the third embodiment will be described. FIG. 1, FIG. 2, FIG. 6, FIG. 9, FIG. 10, FIG. 13, and FIG. 14 are views for explaining an exemplary form of the light-emitting device 3. FIG. 1 is a schematic perspective view of the light-emitting device 3. FIG. 2 is a schematic side view of the light-emitting device 3. FIG. 6 is a schematic bottom view of a package 10B. FIG. 9 is a schematic cross-sectional view of the light-emitting device 3 taken along cross-sectional line IX-IX in FIG. 1. FIG. 10 is a schematic cross-sectional view of the package 10A taken along cross-sectional line X-X in FIG. 6. FIG. 13 is a schematic perspective view illustrating an internal state of the package 10B of the light-emitting device 3. FIG. 14 is a schematic top view of the light-emitting device 3 in a state like that in FIG. 13.

All descriptions related to the light-emitting device 1 of the first embodiment, the light-emitting device 2 of the second embodiment, and the components thereof described above apply to the description of the light-emitting device 3 except for the contents that can be said to be inconsistent from the views of FIG. 1, FIG. 2, FIG. 6, and FIGS. 9 to 12 according to the light-emitting device 3. All non-contradictory contents will not be repeated here in order to avoid duplication.

The light-emitting device 3 includes a plurality of components. The plurality of components include the package 10B, the one or more semiconductor laser elements 20, the one or more reflective members 40, and the one or more wirings 60.

### Package 10B

In the package 10B, the one or more metal members 15 include a fourth metal member 154. The fourth metal member 154 is provided on the insulating member 11M so as to cover the second through hole 11H2. The fourth metal member 154 is provided on a surface opposite to the surface on which the second metal member 152 is provided. For example, the second metal member 152 is provided on the lower surface 11B of the insulating member 11M so as to cover the second through hole 11H2, and the fourth metal member 154 is provided on the upper surface 11A of the insulating member 11M so as to cover the second through hole 11H2. By providing the metal members 15 on the upper and lower surfaces of the insulating member 11M, the airtightness of the internal space can be improved.

Because the second through hole 11H2 is covered by the fourth metal member 154 in the package 10B, the second wiring portion 12A2 provided covering the second through hole 11H2 in the package 10 is not necessary in the package 10B.

All the through holes 11H extending from the upper surface 11A to the lower surface 11B of the base 11 are covered by the metal members 15 on both the upper surface 11A side and the lower surface 11B side. Thus, the metal members 15 include the first metal member 151 and the second metal member 152. All the metal members 15 provided on the lower surface 11B of the base 11 can be thinly provided, and the package can be reduced in size.

### Light-Emitting Device 3

In the light-emitting device 3, the one or more wirings 60 include a wiring 60 having one end bonded to the upper surface 21A of the semiconductor laser element 20 and the other end bonded to the fourth metal member 154. In a top view, the one or more wirings 60 bonded to the fourth metal member 154 and the second through hole 11H2 do not overlap each other. In the light-emitting device 3, by providing the fourth metal member 154, the length of the wiring 60 can be shortened and an electrical load on the wiring 60 can be reduced.

Although each of the embodiments according to the present invention has been described above, the light-emitting device according to the present invention is not strictly limited to the light-emitting device in each of the embodiments. In other words, the present invention can be achieved without being limited to the outer shape or structure of the light-emitting device disclosed by each of the embodiments. The present invention can be applied without requiring all the components being provided. For example, in a case in which some of the components of the light-emitting device disclosed by the embodiments are not stated in the claims, the degree of freedom in design by those skilled in the art such as substitutions, omissions, shape deformations, and material changes is allowed for those components, and then it is specified that the invention stated in the claims is applied to those components.

The light-emitting devices described in the embodiments can be used for a head-mounted display. That is, the head-mounted display can be said to be one usage form to which the present disclosure is applied. The present disclosure is not limited thereto, and can be used in various usage forms such as projectors, lighting, exposure, on-vehicle headlights, and backlights of other displays.

What is claimed is:

1. A light-emitting device comprising:
a package including
a frame portion,
a lid portion,
a base having an upper surface and a lower surface, the base having a thickness in a range from 100 μm to 500 μm, and
a first metal member arranged on the upper surface or the lower surface of the base, the first metal member having a thickness in a range from 10 μm to 150 μm; and
a semiconductor laser element disposed in a sealed internal space of the package, wherein
the base includes an insulating member having an upper surface and a lower surface respectively defining the upper surface and the lower surface of the base,
the insulating member defines a first through hole extending from the upper surface to the lower surface of the insulating member,
the base includes a first conductive member arranged in the first through hole,
the first metal member is arranged on the upper surface or the lower surface of the insulating member such that the first metal member covers the first through hole, and
the semiconductor laser element is electrically connected to the first conductive member and the first metal member.

2. The light-emitting device according to claim 1, further comprising
a second metal member having a thickness in a range from 10 μm to 150 μm, wherein
the insulating member defines a second through hole extending from the upper surface to the lower surface,
the base includes a second conductive member arranged in the second through hole,
the second metal member is arranged on the upper surface or the lower surface of the insulating member such that the second metal member covers the second through hole, and
the semiconductor laser element is electrically connected to the second conductive member and the second metal member.

3. The light-emitting device according to claim 2, wherein the first metal member and the second metal member are arranged on a same surface of the insulating member.

4. The light-emitting device according to claim 2, further comprising
a plurality of metal members with all of the plurality of metal members being arranged on the upper surface or the lower surface of the insulating member, and each of the plurality of metal members having a thickness in a range from 10 μm to 150 μm, the plurality of metal members including at least the first metal member and the second metal member, wherein
the insulating member defines a plurality of through holes with all of the plurality of through holes extending from the upper surface to the lower surface of the insulating member, the plurality of through holes including at least the first through hole and the second through hole,
each of the plurality of through holes is covered by a corresponding one of the plurality of metal members.

5. The light-emitting device according to claim 1, further comprising
a third metal member having a thickness in a range from 10 μm to 150 μm, wherein
the first metal member is arranged on the lower surface of the insulating member,
the third metal member is arranged on the upper surface of the insulating member without covering the first through hole, and
in a top view, a part of the first metal member and a part of the third metal member overlap each other.

6. The light-emitting device according to claim 2, further comprising:
a third metal member having a thickness in a range from 10 μm to 150 μm; and
a fourth metal member having a thickness in a range from 10 μm to 150 μm, wherein
the first metal member is arranged on the lower surface of the insulating member,
the third metal member is arranged on the upper surface of the insulating member such that the third metal member covers the first through hole,
the second metal member is arranged on the lower surface of the insulating member, and
the fourth metal member is arranged on the upper surface of the insulating member such that the fourth metal member covers the second through hole.

7. The light-emitting device according to claim 5, wherein the semiconductor laser element is disposed on an upper surface of the third metal member.

8. The light-emitting device according to claim 7, further comprising
a reflective member disposed in the internal space of the package, the reflective member being configured to reflect light emitted from the semiconductor laser element.

9. The light-emitting device according to claim 7, wherein a thickness of the insulating member is greater than the thickness of the first metal member and is equal to or more than a sum of the thickness of the first metal member and the thickness of the third metal member.

10. The light-emitting device according to claim 1, wherein
an internal volume of the internal space of the package is in a range from 0.357 mm³ to 12.96 mm³, and
the internal space of the package is a sealed space satisfying a condition that an actually measured leak amount (Pa·m³/sec) of helium gas is less than 1.0×10⁻⁷ Pa·m³/sec when a bombing pressure (Pa) of helium gas is 0.5 MPa, a pressurization time (h) of bombing is 1 h, and a dwell time (h) is within 0.1 h in a measurement based on an immersion method (bombing method) in a standard of JIS Z2331: 2006.

11. The light-emitting device according to claim 1, wherein
an internal volume of the internal space of the package is in a range from 0.357 mm³ to 12.96 mm³, and
the internal space of the package is a sealed space satisfying a condition that an actually measured leak amount (Pa·m³/sec) of helium gas is less than 1.0×10⁻⁹ Pa·m³/sec when a bombing pressure (Pa) of helium gas is 0.5 MPa, a pressurization time (h) of bombing is 1 h, and a dwell time (h) is within 5 h in a measurement based on an immersion method (bombing method) in a standard of JIS Z2331: 2006.

12. A light-emitting device comprising:
a package including
a frame portion,
a lid portion,
a base having an upper surface and a lower surface, the base having a thickness from the upper surface to the lower surface in a range from 100 μm to 500 μm, and
a sealing member provided on the upper surface or the lower surface of the base, the sealing member having a thickness in a range from 10 μm to 150 μm; and
a semiconductor laser element disposed in a sealed internal space of the package, wherein
the base includes an insulating member having an upper surface and a lower surface respectively defining the upper surface and the lower surface of the base,
the insulating member defines a first through hole extending from the upper surface to the lower surface,
the base includes a first conductive member arranged in the first through hole,
the sealing member is arranged on the upper surface or the lower surface of the insulating member such that the sealing member covers the first through hole, and
the semiconductor laser element is electrically connected to the first conductive member.

13. The light-emitting device according to claim 12, wherein
an internal volume of the internal space of the package is in a range from 0.357 mm³ to 12.96 mm³, and
the internal space of the package is a sealed space satisfying a condition that an actually measured leak amount (Pa·m³/sec) of helium gas is less than 1.0×10⁻⁷ Pa·m³/sec when a bombing pressure (Pa) of helium gas is 0.5 MPa, a pressurization time (h) of bombing is 1 h, and a dwell time (h) is within 0.1 h in a measurement based on an immersion method (bombing method) in a standard of JIS Z2331: 2006.

14. The light-emitting device according to claim 12, wherein
an internal volume of the internal space of the package is in a range from 0.357 mm³ to 12.96 mm³, and
the internal space of the package is a sealed space satisfying a condition that an actually measured leak amount (Pa·m³/sec) of helium gas is less than 1.0×10⁻⁹ Pa·m³/sec when a bombing pressure (Pa) of helium gas is 0.5 MPa, a pressurization time (h) of bombing is 1 h, and a dwell time (h) is within 5 h in a measurement based on an immersion method (bombing method) in a standard of JIS Z2331: 2006.
